(19) United States
(12) Patent Application Publication
(10) Pub. No.: US 2012/0162935 A1
(43) Pub. Date: Jun. 28, 2012

(54) CIRCUIT BOARD

(75) Inventors: KUO-HSIANG OUYANG, Tu-Cheng (TW); YAO-SHUN TSENG, Tu-Cheng (TW); YI-CHON LIN, Tu-Cheng (TW); HSUAN-JUNG CHEN, Tu-Cheng (TW)

(73) Assignee: HON HAI PRECISION INDUSTRY CO., LTD., Tu-Cheng (TW)

(21) Appl. No.: 13/108,999

(22) Filed: May 17, 2011

(30) Foreign Application Priority Data
Dec. 23, 2010 (TW) 99145479

(51) Int. Cl. H05K 1/18

(52) U.S. Cl. 361/749; 361/748

(57) ABSTRACT

A circuit board includes an induction coil, a ground cable, and an audio signal cable. The induction coil and the audio signal cable are respectively allocated at the two sides of the ground cable. The induction coil and the audio signal cable are spaced a predetermined distance apart. The predetermined distance is equal to or greater than an effective inductive distance of the induction coil.

### BACKGROUND

1. Technical Field

The present disclosure relates to a circuit board.

2. Description of Related Art

Some electronic devices include a number of capacitive keys and a voice source apparatus. Because the capacitive keys and the voice source apparatus may interfere with each other, the capacitive keys and the voice source apparatus are often arranged on different flexible circuit boards, which increases the size and cost of the electronic device.

Therefore, what is needed is a circuit board to alleviate the limitations described above.

### BRIEF DESCRIPTION OF THE DRAWINGS

The components in the drawings are not necessarily drawn to scale, the emphasis instead being placed upon clearly illustrating the principles of a circuit board.

Moreover, in the drawings, like reference numerals designate corresponding parts throughout the several views.

FIG. 1 is an isometric view of an exemplary embodiment of a circuit board.

FIG. 2 is an layout view of the circuit board of FIG. 1.

### DETAILED DESCRIPTION

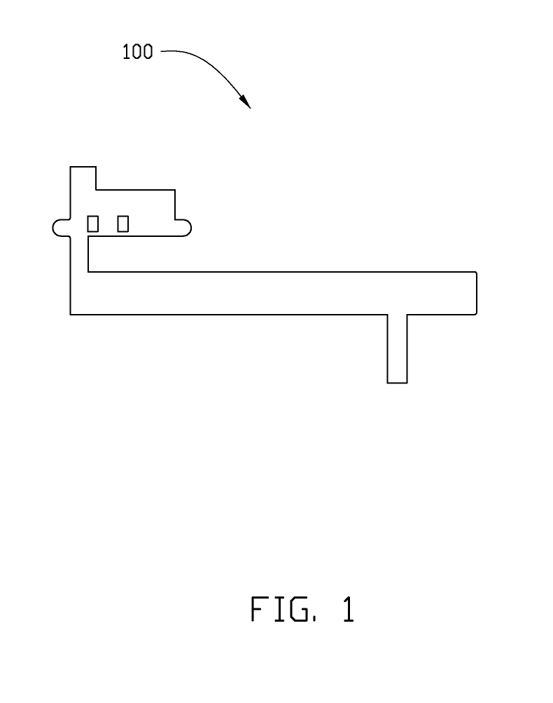

Referring to FIG. 1, a circuit board 100 is disclosed as an exemplary embodiment. The circuit board 100 is a flexible circuit board for an electronic device with a number of capacitive keys, such as a mobile phone, or an electronic reader.

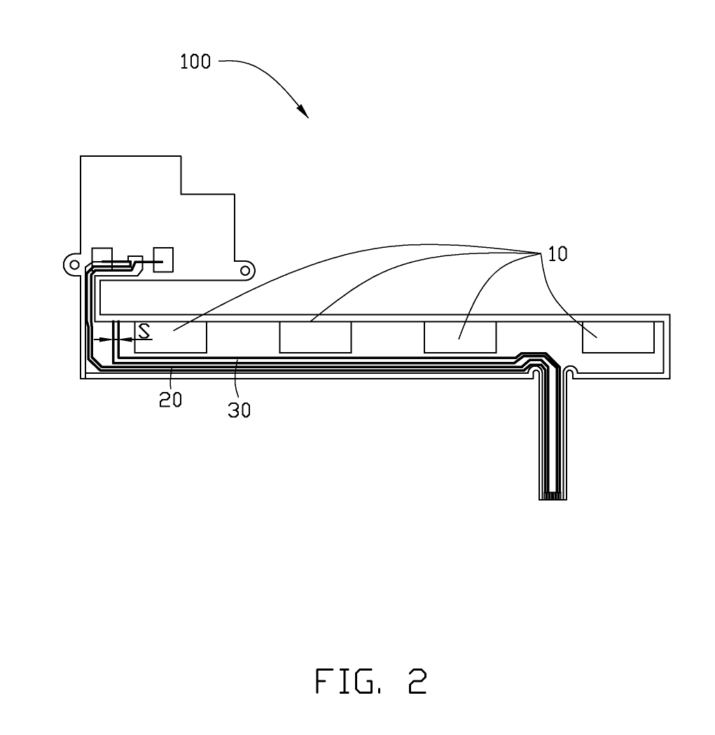

Referring to FIG. 2, the circuit board 100 includes an induction coil 10 of all the capacitive keys, an audio signal cable 20 allocated below the coil 10, and a ground cable 30. The coil 10 and the cable 20 are spaced a predetermined distance apart. A portion of the ground cable 30 extends between the coil 10 and the cable 20. The predetermined distance is equal to or greater than the effective inductive distance of the coil 10. The coil 10 would be interfered with by a source if the distance between the source and the coil 10 were less than the inductive distance. That is, for example, if the inductive distance of the coil 10 were less than the distance between the interference sources such as the cable 20 and the coil 10, the coil 10 would be interfered with by the cable 20.

In the embodiment, the width W of the ground cable 30 is about 1.5 times the inductive distance. Thus, the coil 10 will not be interfered with by the cable 20. In another embodiment, the width W of the ground cable 30 is greater than 1.5 times the inductive distance, which assures the coil 10 and the cable 20 will not interfere with each other.

With such configuration, the coil 10 and the cable 20 can be arranged on the same circuit board 100, and will not interfere with each other, because the width W of the ground cable 30 is equal to or greater than 1.5 times the inductive distance.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A circuit board comprising:
an induction coil;
a ground cable; and
an audio signal cable;
wherein the induction coil and the audio signal cable are respectively allocated at two sides of the ground cable, the induction coil and the audio signal cable are spaced a predetermined distance apart, and the predetermined distance is equal to or greater than an effective inductive distance of the induction coil.

2. The circuit board as described in claim 1, wherein the circuit board is a flexible circuit board.

3. The circuit board as described in claim 1, wherein the predetermined distance is equal to 1.5 times the inductive distance.
